(19) United States
(12) Patent Application Publication
(10) Pub. No.: US 2007/0139109 A1
(43) Pub. Date: Jun. 21, 2007

(54) CLASS D AMPLIFIER WITH START-UP CLICK NOISE ELIMINATION

(76) Inventors: Jun Honda, El Segundo, CA (US); Jong-Deog Jeong, Rancho Palos Verdes, CA (US)

Correspondence Address: OSTROLENK FABER GERB & SOFFEN, 1180 AVENUE OF THE AMERICAS, NEW YORK, NY, 100368403, US

(21) Appl. No.: 11/612,933

(22) Filed: Dec. 19, 2006

Related U.S. Application Data
(60) Provisional application No. 60/753,237, filed on Dec. 21, 2005.

(51) Int. Cl. H03F 3/217

(52) U.S. Cl. 330/251

(57) ABSTRACT

A circuit for minimizing audible click noise upon the startup of a Class D audio power amplifier. The amplifier including a power switching output stage and a driver for driving the output stage receiving a driving signal and a shutdown signal, the shutdown signal preventing switching of the output stage. The circuit including a comparator connected to the driver for generating the driving signal; an error amplifier receiving an audio input signal; a first feedback loop for connecting the output stage as input to an input of the error amplifier, an output of the error amplifier being connected to an output of the comparator; and a circuit coupled to the error amplifier preventing a capacitor connected to the error amplifier from excessively charging, thereby preventing noise in the output stage when the shutdown signal is removed.

### CROSS-REFERENCE TO RELATED APPLICATION

This application is based on and claims priority to U.S. Provisional Patent Application Ser. No. 60/753,237, filed on Dec. 21, 2005 and entitled CLASS D AMPLIFIER WITH START-UP CLICK NOISE ELIMINATION, the entire contents of which is hereby incorporated by reference herein.

### BACKGROUND OF THE INVENTION

The present invention relates to Class D audio power amplifier ICs, and more specifically to minimizing audible click noise upon the startup of Class D audio power amplifiers.

During a shutdown period in a Class D amplifier having a feedback loop, an output node of an error amplifier inside the feedback loop goes to an extreme high value due to its high gain and offset. An integration element of the error amplifier is charged to this high value.

When the Class D amplifier tries to resume oscillation upon release of shutdown, the output of the error amplifier requires time for the voltage across a capacitor to return to a steady state value. This excessive time, required for settling the voltage across the capacitor back to normal voltage, creates an imbalance in the duty cycle at the output of a PWM comparator, which causes unwanted output voltage (noise) to be supplied to the loudspeaker. Hence, click noise from the loudspeaker is heard.

To correct this unwanted characteristic, i.e., the click noise, a speaker cutoff relay, which is a bulky, costly, space wasting electromechanical device has been inserted between the amplifier and the loudspeaker.

FIG. 1 illustrates an example of a Class D audio amplifier 20 having a feedback loop forming a self oscillating PWM modulator. The Class D audio amplifier 20 includes a bridge driver 9 that receives a shutdown input signal at SD pin and a COMPOUT PWM signal at the PWM pin. The half bridge driver 9 drives a pair of high and low side MOSFET switches 10 and 11 connected in a half bridge.

A low pass LC filter comprising an inductor 12 and a capacitor 13 is coupled at an output stage VS connecting the high and low switches 11 and 10 to remove the PWM high frequency switching signal. A first terminal of the inductor 12 is coupled to the output stage VS, while the second terminal of the inductor 12 is used for providing the output signal OUT of the Class D audio amplifier 20. The capacitor 13 is connected between a common and the second terminal of the inductor 12. The loudspeaker load is coupled between OUT and ground.

The COMPOUT signal is generated by a comparator 8, which compares a signal OPOUT of the error amplifier 7 to a reference potential, here ground. In the embodiment shown, a positive terminal of the error amplifier 7 is connected to the common and a negative terminal is connected to the audio signal source V_{IN} 16 through a resistor 15 and to the feedback signal from the output stage VS through a resistor 14. An integration capacitor 6 couples the negative terminal and the output of the error amplifier 7.

FIG. 2 illustrates performance of the Class D audio amplifier 20 over time. As shown, during the shutdown period t1, i.e., when the shutdown signal is provided to SD pin of the bridge driver 9, the voltage on the integration capacitor 6 is charged to a level of the supply voltage Vₛₛ of the error amplifier 7. V_{AA} and Vₛₛ are the floating input positive and negative supply voltages to the error amplifier 7. The output Vₛ has a high impedance state (high Z) at this time.

When the shutdown signal to SD pin of the bridge driver 9 is terminated, the low side switch 10 turns on. However, it takes time t2 to charge the output of the PWM comparator 8 due to the voltage charged on the integration capacitor 6, causing an unbalanced PWM duty cycle. This unbalanced PWM duty cycle generates unwanted noise in the speaker output during t2 and t3 periods. Thus the charged voltage on the capacitive component, i.e., the integration capacitor 6, of the error amplifier 7 creates a problem.

### SUMMARY OF THE INVENTION

It is an object of the present invention to provide noiseless startup for a Class D audio power amplifier, and thus eliminate the need for a speaker cut off switch.

It is another object of the present invention to eliminate a bulky, expensive and unreliable speaker cutoff relay, providing system cost and space savings.

The invention comprises a circuit for minimizing audible click noise upon the startup of a Class D audio power amplifiers. The circuit is used with a Class D audio amplifier having a power switching output stage; a driver for driving the output stage receiving a driving signal for driving the switching of the output stage and a shutdown signal; the shutdown signal preventing switching of the output stage; the circuit including a comparator connected to the driver for generating the driving signal; an error amplifier receiving an audio input signal; a first feedback loop for connecting the output stage as input to an input of the error amplifier, an output of the error amplifier being connected to an input of the comparator; and a circuit coupled to the error amplifier preventing a capacitor connected to the error amplifier from excessively charging, thereby preventing noise in the output stage when the shutdown signal is removed. The circuit coupled to the error amplifier being a second feedback loop coupling the output of the comparator to the error amplifier input. More specifically, the second feedback loop causes the error amplifier to oscillate when the shutdown signal is present to prevent the integration capacitor connected to the error amplifier from excessively charging, thereby preventing noise in the output stage when the shutdown signal is removed.

Other features and advantages of the present invention will become apparent from the following description of the invention that refers to the accompanying drawings.

### BRIEF DESCRIPTION OF THE DRAWINGS

FIG. 1 is a diagram of a Class D audio amplifier having a feedback loop as used in the prior art;

FIG. 2 shows waveforms present in the Class D audio amplifier of FIG. 1;

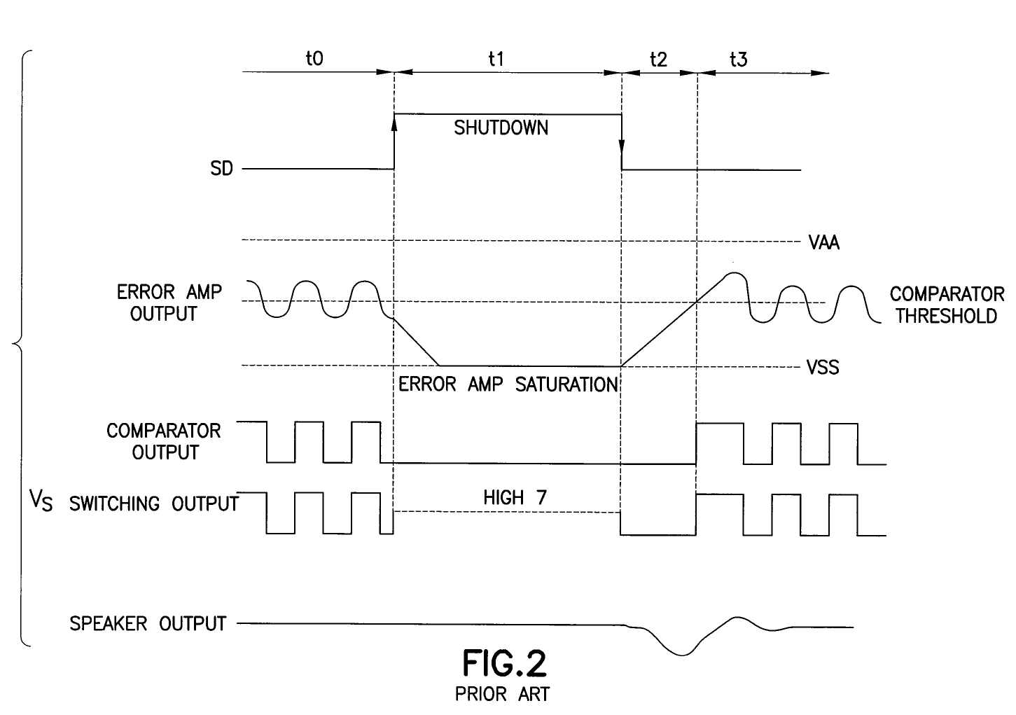

FIG. 3 is a diagram of a Class D audio amplifier according to the invention having a second feedback loop;

FIG. 4 shows waveforms of the Class D audio amplifier of FIG. 3;

FIGS. 5a and 5b are graphs of startup waveforms for the prior art circuit of FIG. 1 and of the present invention circuit of FIG. 3, respectively; and

FIG. 6 is a diagram of a typical application of an IC including the present invention.

### DETAILED DESCRIPTION OF EMBODIMENTS OF THE INVENTION

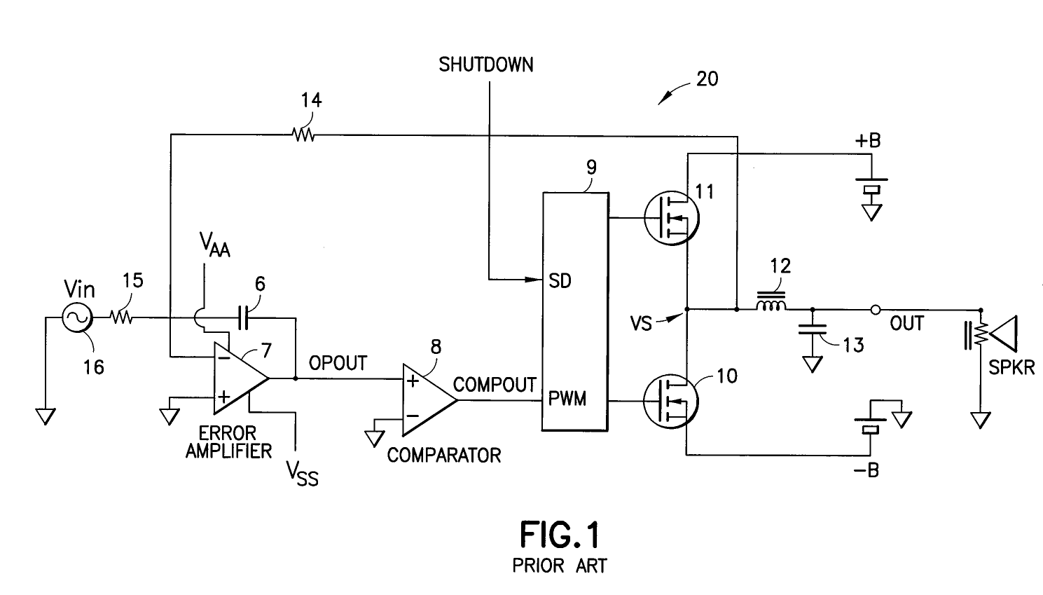

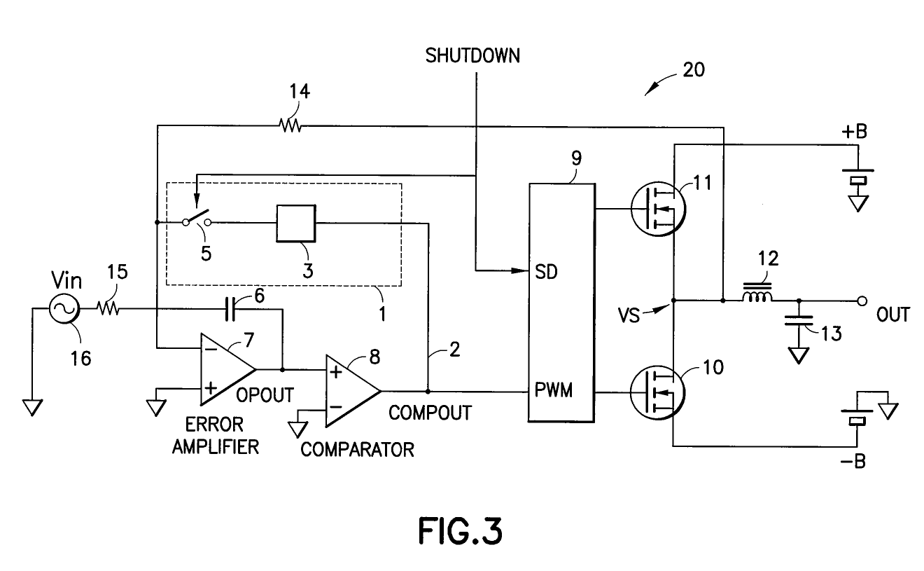

FIG. 3 illustrates a Class D audio amplifier 30 embodying the present invention. In addition to all the components described above with reference to the Class D audio amplifier 20 of FIG. 1, the Class D audio amplifier 30 includes a locally added feedback path 1 between the comparator output and the error amplifier input. In the embodiment shown, the feedback path 1 couples the output of the comparator 8 to the negative input terminal of the error amplifier 7. The added feedback path 1 includes a switch 5 controlled by the shutdown signal provided to the SD pin of the half bridge driver 9. The switch 5 is preferably a semiconductor switch, e.g., a MOSFET. The added feedback path 1, when closed, forms an oscillator running at a frequency higher than the normal operating frequency of switching of the half bridge driver 9. That frequency, however, does not have to be higher.

During the shutdown, i.e., when the shutdown signal is ON, the added feedback path 1 is closed creating a local oscillation loop that oscillates while the output stage is in a cutoff state. This operation keeps the voltage across the capacitive component, i.e., the integration capacitor 6, of the error amplifier 7 near the steady state value. In other words, the output voltage of the error amplifier 7 is maintained close to a threshold of the PWM comparator 8, preventing it from charging excessively. The local oscillation loop path overrides the feedback input so that the output of the error amplifier 7 is independent of the status of the output stage. When the shutdown signal is removed, switch 5 is opened and the amplifier returns to normal operation.

Therefore, when the shutdown signal is OFF or terminated, the amplifier begins switching immediately without having an excessive delay that causes offset in the output. Additionally, the Class D audio amplifier 30 provides the capability to compensate for variation of the threshold of PWM comparator 8.

The element 3 in FIG. 3 corresponds to any desired feedback element that can be provided in the feedback path to obtain the desired frequency of oscillation when the shutdown signal is present.

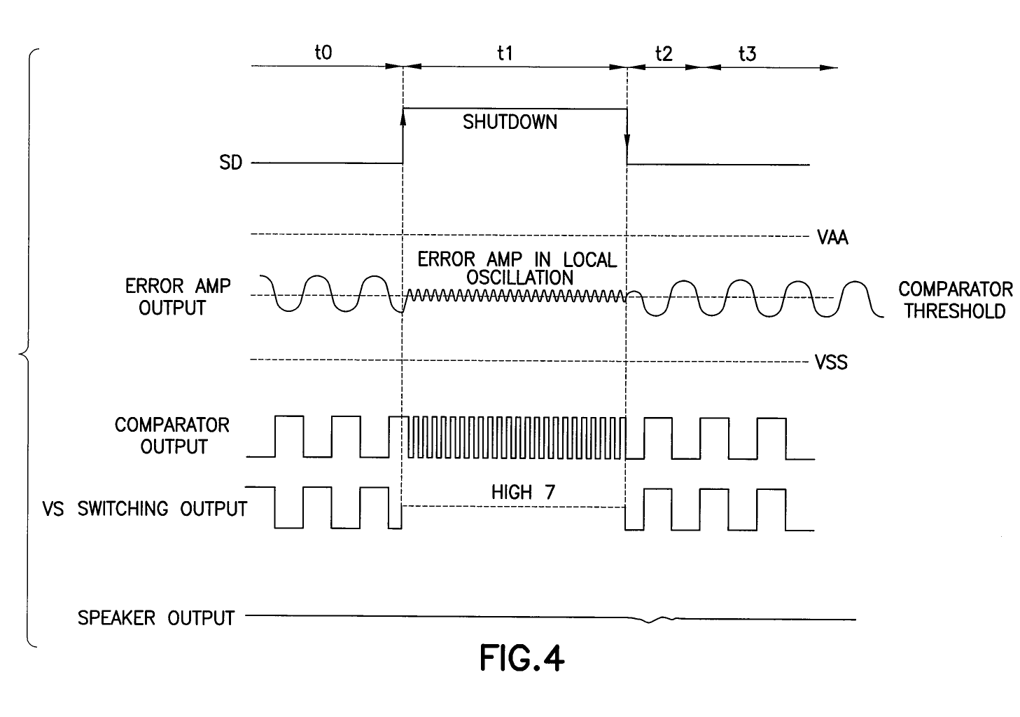

FIG. 4 shows waveforms of the Class D audio amplifier 30. As shown, during the shutdown period t1, the error amplifier 7 stays in local oscillation and the integration capacitor 6 is not charged to the supply voltage Vₛₛ.

When the shutdown signal is set OFF at the beginning of period t2, the low side switch 10 switches on in accordance with the driving PWM signal. Because the capacitor 6 is not charged, there is no delay due to it, and the error amplifier will respond accordingly. An imbalance in the duty cycle of the PWM signal is thus not generated and there is no undesirable noise generated in the speaker output during the t2 or t3 periods. Thus the problem of the charging voltage on the capacitive component 6 in the error amplifier is solved.

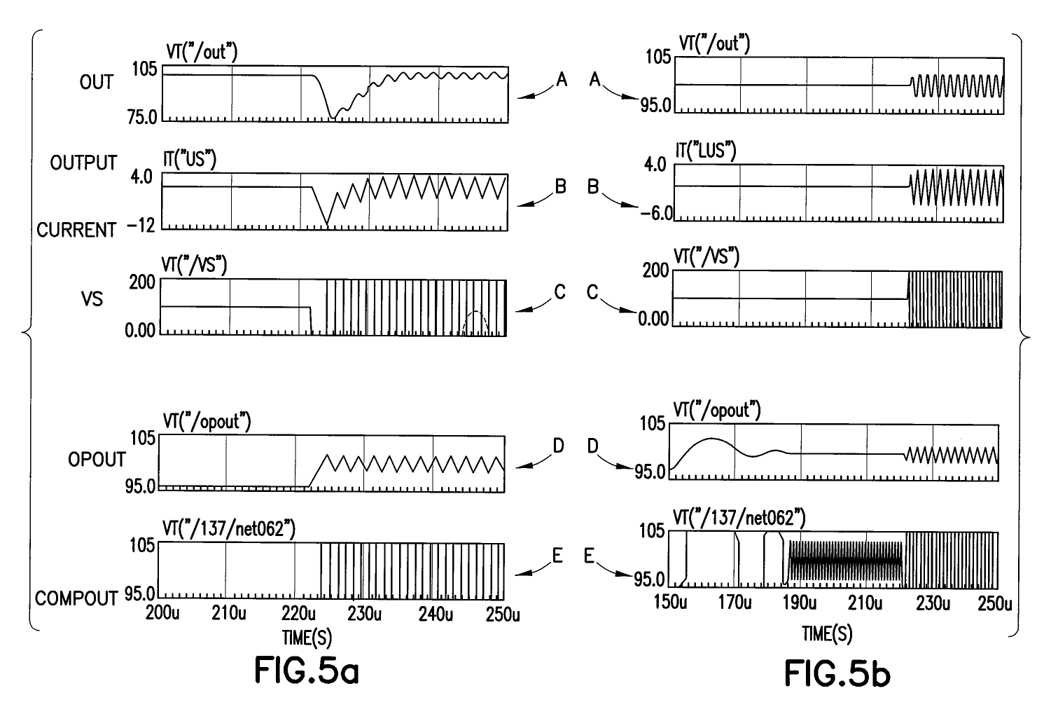

FIGS. 5a and 5b illustrate voltages at different points of the Class D audio amplifier circuits 20 and 30 respectively during shutdown, when shutdown is removed and right after shutdown. Graphs A show voltage variations over time at output stage OUT; graphs B show current in the output inductor; graphs C show voltage variations at the output stage node VS; graphs D show voltage variations at the output of the error amplifier 7 OPOUT; and graphs E show COMPOUT. The two sets of waveforms are plotted against different time bases, so the signals in FIG. 5a are more spread out.

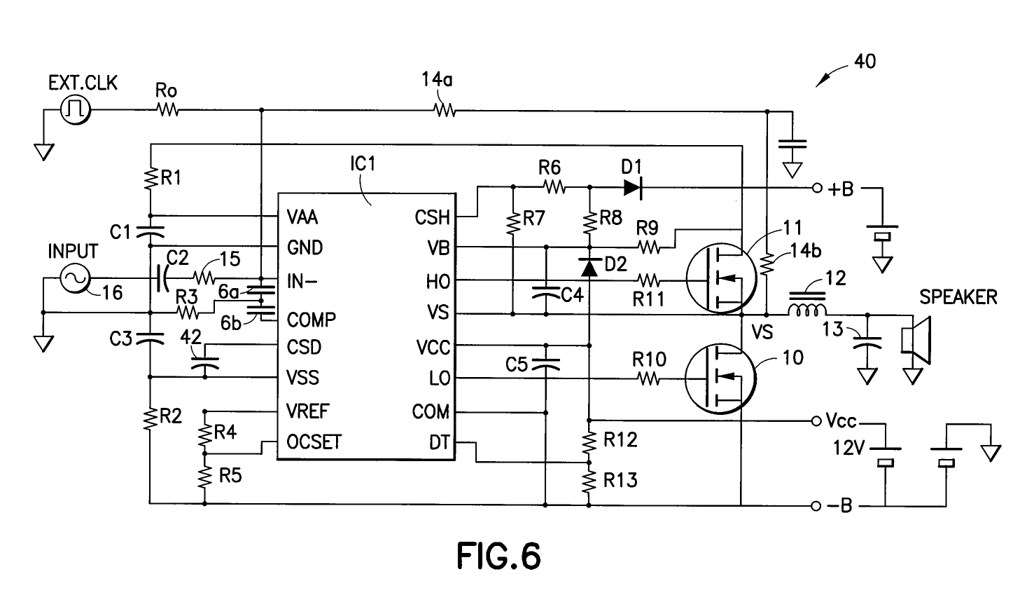

FIG. 6 illustrates a diagram of typical application circuit 40 of the present invention. IC1 is a high voltage, high performance Class D audio amplifier driver with PWM modulator and over-current protection in a 16 pin package.

As shown in FIG. 6, IC1 is designed with a floating input positive supply at VAA pin; analog non inverting input at IN pin; a floating input supply return at GND pin; a phase compensation input at COMP pin; a shutdown timing capacitor 42 at CSD pin; a floating input negative supply at VSS pin; 5V reference voltage for programming OCSET pin at VREF pin; a low side over current threshold setting used as protection control interface especially for half bridge topology at OCSET pin; a dead time program input at DT pin; a low side supply return at COM pin; a low side output at LO pin; a low side logic supply at VCC pin; a high side floating supply return at VS pin; a high side output at HO pin; a high side floating supply at VB pin; and a high side over current sensing input at CSH pin.

The circuit 40 further includes a resistor r1 connected to the switch 11; a resistor r2 connected to VSS pin; a resistor r3 connected between series coupled capacitors 6a and 6b connected between IN and COMP pins; series coupled resistors r4 and r5 connected to VREF and OCSET pins respectively; a resistor r6 connected to CSH pin and a diode D1; a resistor r7 connected between CSH and VS pins; a resistor r8 connected between an anode of the diode d1 and a cathode of the diode d2; series coupled resistors r12 and r13 connected to the anode of the diode d2; a resistor r9 connecting a cathode of a diode d2 to the switch 11; resistors r10 and r11 respectively connecting LO and HO pins to gates of the switches 10 and 11; and feedback loop resistors 14a and 14b connecting the output stage VS to IN pin. A capacitor c1 is coupled between VAA and GND pins; a capacitor c2 series connected between audio input 16 and resistor 15; a capacitor c3 is connected to VSS pin; ; a capacitor c4 is connected between VB and VS pins; a capacitor c5 is connected between VCC and COM pins.

Additionally, circuit 40 illustrates a speaker coupled to the LC filter of inductor 12 and capacitor 13, at the output of the audio amplifier, and an optional external clock can be coupled to the circuit via a register r0 for external synchronization.

The high performance Class D audio amplifier driver 2092 protects high and low side MOSFETs 10 and 11 of the circuit 40 from over current conditions by a programmable bi-directional current sensing. The amplifier scheme, as described above with reference to FIG. 1, is based on analog input self-oscillating PWM.

Although the present invention has been described in relation to particular embodiments thereof, many other variations and modifications and other uses will become apparent to those skilled in the art. It is preferred, therefore, that the present invention not be limited by the specific disclosure herein.

What is claimed is:

1. A circuit for minimizing audible click noise upon the startup of a Class D audio power amplifier, the amplifier comprising a power switching output stage and a driver for driving the output stage receiving a driving signal and a shutdown signal, the shutdown signal preventing switching of the output stage, the circuit comprising:
a comparator connected to the driver for generating the driving signal;
an error amplifier receiving an audio input signal;
a first feedback loop for connecting the output stage as input to an input of the error amplifier, an output of the error amplifier being connected to an input of the comparator; and
a circuit coupled to the error amplifier preventing a capacitor connected to said error amplifier from excessively charging, thereby preventing noise in said output stage when said shutdown signal is removed.

2. The circuit of claim 1, wherein the first feedback loop forms a self-oscillating PWM modulator.

3. The circuit of claim 1, wherein the circuit coupled to the error amplifier is a second feedback loop.

4. The circuit of claim 3, wherein the second feedback loop causes said error amplifier to oscillate when said shutdown signal is present to prevent the capacitor connected to said error amplifier from excessively charging, thereby preventing noise in said output stage when said shutdown signal is removed.

5. The circuit of claim 4, wherein the second feedback loop further comprising a feedback element for setting an oscillation frequency of said error amplifier when said shutdown signal is present.

6. The circuit of claim 5, wherein the oscillation frequency is higher than a switching frequency of said power switching output stage.

7. The circuit of claim 3, wherein the second feedback loop includes a switch controlled by the shutdown signal, whereby, when said shutdown signal is present, said second feedback loop is connected in the circuit and when the shutdown signal is not present, the second feedback loop is disconnected, the second feedback loop causing said error amplifier to oscillate when said shutdown signal is present to prevent the capacitor connected to said error amplifier from excessively charging, thereby preventing noise in said output stage when said shutdown signal is removed.

8. The circuit of claim 7, wherein said switch in said second feedback loop comprises a transistor controlled by said shutdown signal.

9. The circuit of claim 3, wherein the second feedback loop couples the output of the comparator to said error amplifier input.

10. The circuit of claim 9, wherein the output of the comparator comprises a PWM signal and when the shutdown signal is removed, the duty cycle of the PWM signal is balanced and unwanted noise is not generated in the output of the audio power amplifier.

11. The circuit of claim 3, wherein the output of said error amplifier is the input to the second feedback loop.

12. The circuit of claim 1, wherein said capacitor connected to said error amplifier is an integration capacitor.

13. The circuit of claim 1, wherein the circuit is packaged in an integrated circuit package with said driver.
